(19) United States
(12) Patent Application Publication
(10) Pub. No.: US 2009/0051005 A1
(43) Pub. Date: Feb. 26, 2009

(54) METHOD OF FABRICATING INDUCTOR IN SEMICONDUCTOR DEVICE

(76) Inventor: Sung-Ho Kwak, Yeoju-gun (KR)

Correspondence Address: SHERR & VAUGHN, PLLC, 620 HERNDON PARKWAY, SUITE 200, HERNDON, VA, 20170, US

(21) Appl. No.: 12/188,167

(22) Filed: Aug. 7, 2008

(30) Foreign Application Priority Data
Aug. 23, 2007 (KR) 10-2007-0084840

(51) Int. Cl. H01L 29/00; H01L 21/02

(52) U.S. Cl. 257/531; 438/381; 257/E29.001; 257/E21.022

(57) ABSTRACT

A method of fabricating an inductor in a semiconductor device is disclosed. Embodiments include forming a first metal wire in a trench formed by etching a layer of a semiconductor substrate, forming an insulating layer over the substrate including the first metal wire, forming a via hole by etching the insulating layer to expose a portion of the first metal wire, forming a plated layer by electroplating to partially fill the via hole with the plated layer, and forming a second metal wire over the insulating layer including the plated layer.

The present application claims priority under 35 U.S.C. 119 to Korean Patent Application No. 10-2007-0084840 (filed on Aug. 23, 2007), which is hereby incorporated by reference in its entirety.

### BACKGROUND

In radio frequency integrated circuit (RF IC) designs, an inductor is often required for impedance matching. A quality factor (Q) is important for determining performance of a matching circuit as well as inductance of the inductor. The quality factor relates to how much energy an RF semiconductor device is capable of storing and the power it dissipates.

Previously, manufacturers have been unable to obtain a high quality factor required for an RF IC using a standard logic process. To secure a high quality factor, the parasitic resistance, eddy currents and displacement currents flowing into a substrate should be reduced. The quality factor can be raised by reducing resistance of a metal wire used as an inductor. This may be accomplished by increasing the thickness of the wire above a standard thickness, using low-resistance metal such as copper, or by raising an inductor above a lower layer as high as possible.

In an inductor fabricating method according to a related art, a 3-dimensional inductor is fabricated using a bonding wire. In another inductor fabricating method according to a related art, a multi-layered metal layer including at least three stacked layers and metal wires on second and third layers are then simply connected to each other through a plurality of via holes. Hence, the cross-sectional area of the metal wire is increased to reduce a resistance of an inductor. Thus, the quality factor can be enhanced. However, these related art methods cause difficulties in fabrication, have lower reproducibility, and an absence of compatibility with general silicon-based semiconductor process, resulting in increased fabrication times and the like.

### SUMMARY

Embodiments relate to a semiconductor device, and more particularly, to a method of fabricating an inductor in a semiconductor device. Embodiments relate to enhancing a quality factor (Q) of an inductor. Embodiments relate to a method of fabricating an inductor in a semiconductor device, by which a quality factor of an inductor can be enhanced.

Embodiments relate to a method of fabricating an inductor in a semiconductor device which includes forming a first metal wire in a trench formed by etching a layer of a semiconductor substrate, forming an insulating layer over the substrate including the first metal wire, forming a via hole by etching the insulating layer to expose a portion of the first metal wire, forming a plated layer by electroplating to partially fill the via hole with the plated layer, and forming a second metal wire over the insulating layer including the plated layer.

In a method of fabricating an inductor in a semiconductor device according to embodiments, a thickness of a nitride layer of an insulating layer may be raised to increase a thickness of a metal wire. A copper plating layer, which is electrically connected to a metal layer by a depth-increased via hole, may then be additionally plated to increase a thickness of the metal wire. Therefore, the embodiments lower resistance and raise a quality factor, thereby enhancing process reliability and electrical characteristics of device.

### DRAWINGS

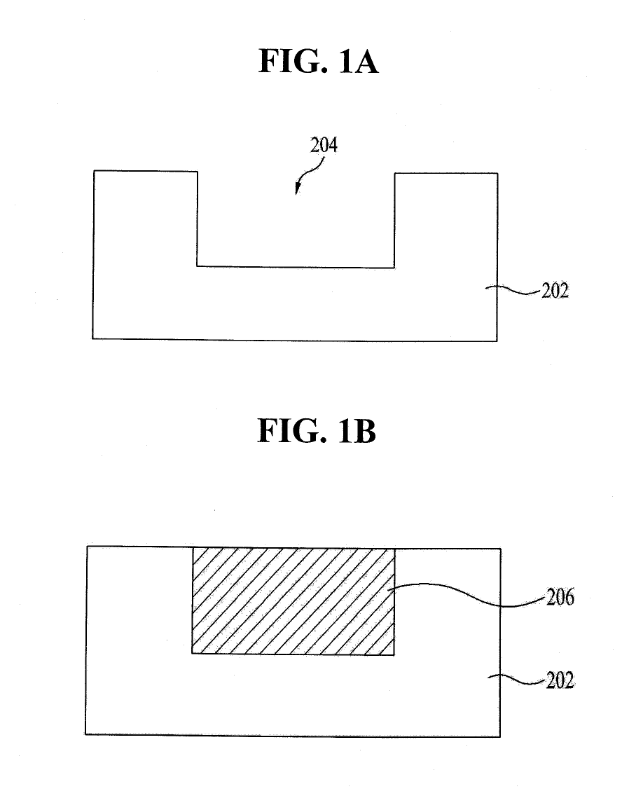

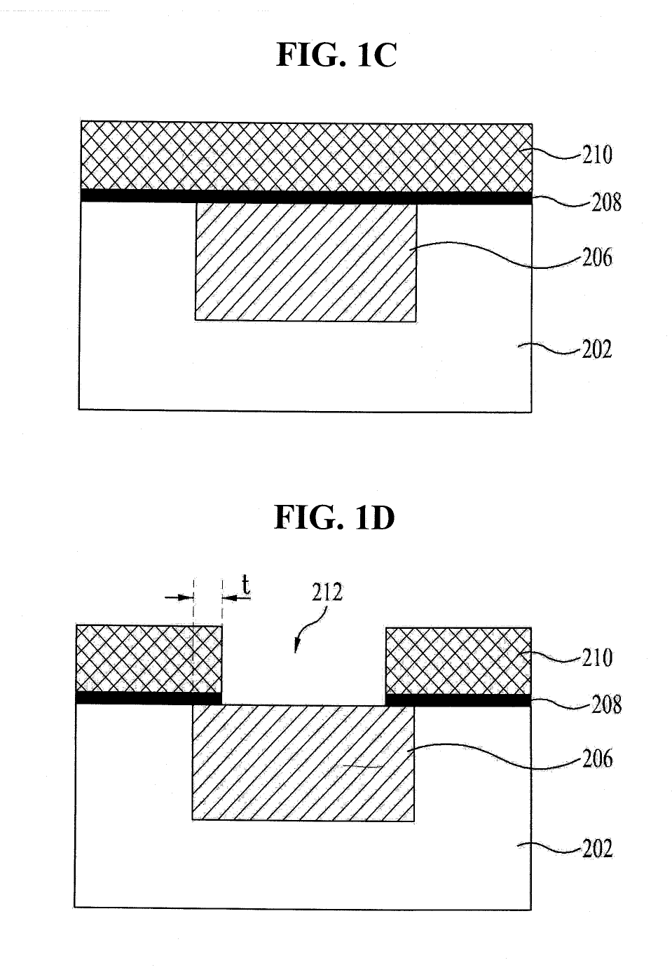

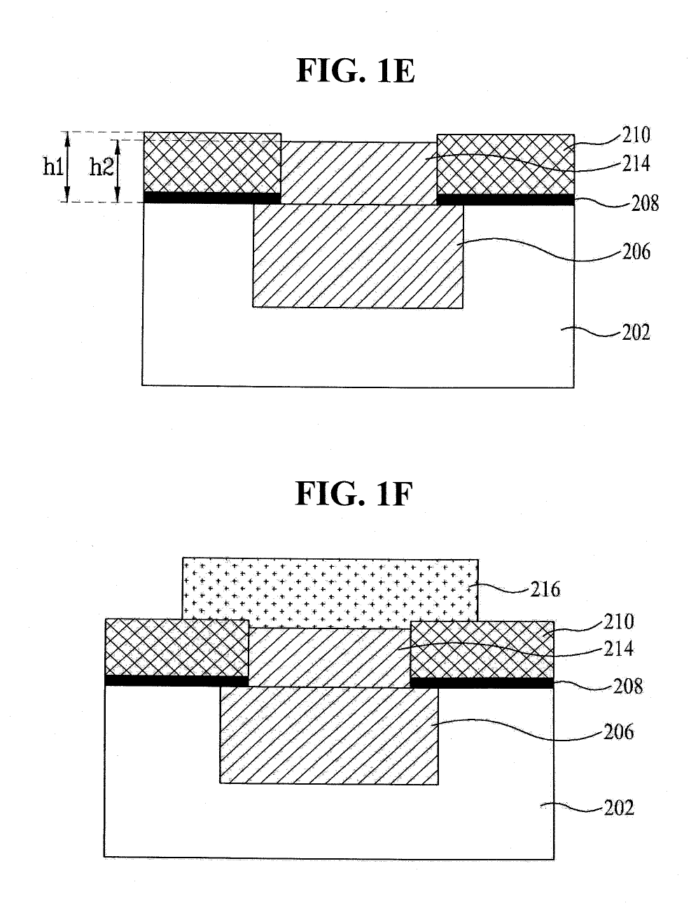

Example FIGS. 1A to 1F are cross-sectional diagram for a method of fabricating an inductor in a semiconductor device according to embodiments.

### DESCRIPTION

Example FIGS. 1A to 1F are cross-sectional diagram for a method of fabricating an inductor in a semiconductor device according to embodiments. Referring to example FIG. 1A, a trench 204 may be formed on a substrate 202 by photolithography. The trench 204 establishes an area for forming a metal wire.

Referring to example FIG. 1B, a first metal wire 206 may be formed in the trench 204 on the substrate 202. For instance, metal based material may be deposited over the substrate 202 by Plasma Enhanced Chemical Vapor Deposition (PECVD) or Sputtering to fill the trench 294. The deposited metal based material may be planarized by Chemical Mechanical Polishing (CMP) to form the first metal wire 206. The first metal wire 206 may be formed of at least one selected from the group consisting of Cu, Al and an alloy thereof.

Referring to example FIG. 1C, an insulating layer may be formed over the substrate 202 including the first metal wire 206. The insulating layer may include a nitride layer 208 and an oxide layer 210. For instance, the nitride layer 208 and the oxide layer 210 may be sequentially stacked over both of the first metal wire 206 and the substrate 202. Each of the nitride and oxide layers 208 and 210 may be formed by Chemical Vapor Deposition (CVD), Plasma Enhanced Chemical Vapor Deposition (PECVD) or the like. In particular, the nitride layer 208 may be formed 630 Å˜700 Å thick and the oxide layer may be formed approximately 6000 Å˜20,000 Å thick, for example. Optionally, a diffusion preventing layer may be formed between the first metal wire 206 and the insulating layer to prevent diffusion and oxidation of the metal wire. The diffusion preventing layer may be formed of Ta, TaN, TaSiN, TiN, TiSiN, WN, WSiN or the like.

Referring to example FIG. 1D, a via hole 212 may be formed by perforating both of the oxide and nitride layers 210 and 208 by photolithography to expose a portion of the first metal wire 206. Specifically, the via hole 212 may have a width smaller than that of the first metal wire 206. For instance, a distance (hereinafter called ‘align margin’) between one sidewall of the via hole 212 and one sidewall of the trench 206 having the first metal wire 206 formed therein can be set to approximately 150˜250 nm. Thus, the align margin is reserved between the via hole 212 and the first metal wire (e.g., Cu wire) 206 to prevent a surface of the first metal wire 206 from being exposed and contaminated by a subsequent etch process for forming an upper metal wire (e.g., Al wire).

Referring to example FIG. 1E, a Cu-plated layer 214 may be formed over the first metal wire (e.g., Cu wire) 206 exposed through the formation of the via hole 212. The Cu-plated wire 214 may be formed by growing Cu over the first metal wire (e.g., Cu wire) 206 by electrochemical plating (ECP). Specifically, a height h2 of the CU-plated layer 214 may be smaller than a height h1 of the insulating layer including the nitride and oxide layers 208 and 210. Therefore, the Cu-plated layer 241 may fill the gap of the via hole 212 to a height lower than the insulating layer.

Referring to example FIG. 1F, a second metal wire 216 may be formed over both of the Cu-plated layer 214 and the oxide layer 210. For instance, after a metal layer (e.g., Al layer) has been deposited over both of the Cu-plated layer 214 and the oxide layer 210 by PECVD, sputtering or the like, the deposited metal layer may be patterned by photolithography to form the second metal wire 216. The second metal wire 216 may be formed of at least one selected from the group consisting of Cu, Al and an alloy thereof.

Optionally, a diffusion preventing layer may be formed between the second metal wire 216 and the insulating layer to prevent diffusion and oxidation of the metal wire. In this case, the diffusion preventing layer may be formed of Ta, TaN, TaSiN, TiN, TiSiN, WN, WSiN or the like.

Accordingly, embodiments provide effects and/or advantages including the following. First, a thickness of a nitride layer of an insulating layer may be raised to increase a thickness of a metal wire. A copper plating layer, which is electrically connected to a metal layer by a depth-increased via hole, is then additionally plated to raise a thickness of the metal wire. Therefore, embodiments offer lower resistance and a higher quality factor, thereby enhancing process reliability and electrical characteristics of device.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a first metal wire in a trench formed by etching a layer of a semiconductor substrate;
forming an insulating layer over the substrate including the first metal wire;
forming a via hole by etching the insulating layer to expose a portion of the first metal wire;
forming a plated layer by electroplating to partially fill the via hole with the plated layer; and
forming a second metal wire over the insulating layer including the plated layer.

2. The method of claim 1, wherein the via hole is formed to have a width smaller than a width of the first metal wire.

3. The method of claim 1, wherein the via hole exposes a central portion of the first metal wire, but leaves a peripheral portion of the upper surface of the first metal wire unexposed.

4. The method of claim 1, wherein a distance between one sidewall of the via hole and one sidewall of the trench having the first metal wire formed therein is approximately 150 nm˜250 nm.

5. The method of claim 1, wherein forming the insulating layer comprises:
forming a nitride layer over the substrate including the first metal wire; and
forming an oxide layer over the nitride layer.

6. The method of claim 5, wherein the nitride layer is formed to be approximately 630 Å˜700 Å thick.

7. The method of claim 5, wherein the oxide layer is formed to be approximately 6,000 Å˜20,000 Å thick.

8. The method of claim 1, wherein each of the first and second metal wires is formed of one of Al and Cu.

9. The method of claim 1, wherein the plated layer is formed of Cu.

10. The method of claim 1, comprising forming a diffusion preventing layer between the first metal wire and the insulating layer.

11. The method of claim 10, wherein the diffusion preventing layer is formed of one selected from the group consisting of Ta, TaN, TaSiN, TiN, TiSiN, WN and WSiN.

12. An apparatus comprising:
a semiconductor substrate having a trench formed therein;
a first metal wire filling the trench;
an insulating layer over the substrate including the first metal wire, the insulating layer having a via hole over a portion of the first metal wire;
a plated layer partially filling the via hole; and
a second metal wire covering the plated layer and a portion of the insulating layer.

13. The apparatus of claim 12, wherein the insulating layer comprises nitride and oxide layers sequentially stacked over the substrate including the first metal wire.

14. The apparatus of claim 12, wherein the via hole has a width smaller than that of the first metal layer.

15. The apparatus of claim 13, wherein the nitride layer is approximately 630 Å˜700 Å thick.

16. The apparatus of claim 13, wherein the oxide layer is approximately 6,000 Å˜20,000 Å thick.

17. The apparatus of claim 12, wherein each of the first and second metal wires comprises at least one of Al and Cu.

18. The apparatus of claim 12, wherein the plated layer comprises Cu.

19. The apparatus of claim 12, wherein one sidewall of the via hole and one sidewall of the trench having the first metal wire formed therein are separated by a distance of approximately 150 nm˜250 nm.

20. The apparatus of claim 12, wherein first metal wire, insulating layer, plated layer and second metal wire form part of an inductor.
